(19) United States
(12) Patent Application Publication
(10) Pub. No.: US 2007/0240757 A1
(43) Pub. Date: Oct. 18, 2007

(54) Solar cells using arrays of optical rectennas

(75) Inventors: Zhifeng Ren, Newton, MA (US); Krzysztof Kempa, Billerica, MA (US); Yang Wang, Allston, MA (US)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: The Trustees of Boston College

(21) Appl. No.: 11/250,932

(22) Filed: Oct. 14, 2005

Related U.S. Application Data
(60) Provisional application No. 60/619,262, filed on Oct. 15, 2004.

(51) Int. Cl. H01L 31/00

(52) U.S. Cl. 136/256

(57) ABSTRACT

The present invention discloses a solar cell comprising a nanostructure array capable of accepting energy and producing electricity. In an embodiment, the solar cell comprises an at least one optical antenna having a geometric morphology capable of accepting energy. In addition, the cell comprises a rectifier having the optical antenna at a first end and engaging a substrate at a second end wherein the rectifier comprises the optical antenna engaged to a rectifying material (such as, a semiconductor). In addition, an embodiment of the solar cell comprises a metal layer wherein the metal layer surrounds a length of the rectifier, wherein the optical antenna accepts energy and converts the energy from AC to DC along the rectifier. Further, the invention provides various methods of efficiently and reliably producing such solar cells.

### RELATED APPLICATIONS

This application claims the benefit of U.S. Provisional Application Ser. No. 60/619,262, filed Oct. 15, 2004, the entirety of which is hereby incorporated herein by reference.

### GOVERNMENT SUPPORT

The present invention was made with partial support from The US Army Natick Soldier Systems Center under Grant Number DAAD16-02-C-0037 and partly by NSF under the grant NIRT 0304506. The United States Government retains certain rights to the invention.

### FIELD OF INVENTION

The embodiments disclosed herein relate to nanoscale energy conversion devices having optical rectennas, and more particularly to high-efficiency solar cells having arrays of optical rectennas capable of receiving and transmitting solar energy and converting the solar energy into direct current electricity.

### BACKGROUND OF THE INVENTION

The concept of using a rectifying antenna (rectenna) to collect solar energy was first proposed by R. L. Bailey in 1972; Since then, different approaches have been taken toward a practical fabrication of solar cells using optical rectennas. To date, however, no substantial progresses in practice have been reported due to major difficulties in achieving large-scale metallic nanostructures at low cost.

Recently, periodic and random arrays of multi-walled carbon nanotubes (MWCNTs) have been synthesized on various substrates. Each nanotube in the array is a metallic rod of about 10-100 nm in diameter and 200-1000 nm in length. Therefore, one can view interaction of these arrays with the electromagnetic radiation as that of an array of dipole antennas. MWCNTs arrays have been studied in order to determine the antenna-like interactions, since the most efficient antenna interaction occurs when the length of the antennas is of the order of the wavelength of the incoming radiation.

U.S. Pat. No. 6,038,060, U.S. Pat. No. 6,258,401, and U.S. Pat. No. 6,700,550 disclose various attempts at producing optical antenna arrays. However, there remains a need in the art for high energy conversion devices that employ optical antennas capable of receiving energy and converting AC current into a DC current. In addition, there is a need in the art for an efficient, reproducible method of producing such solar cells.

### SUMMARY OF THE INVENTION

The present invention discloses a solar cell comprising a planar substrate having a top side and a bottom side. The solar cell comprises an at least one optical antenna having a geometric morphology capable of accepting energy. In addition, the cell comprises a rectifier having the optical antenna at a first end and engaging the substrate at a second end wherein the rectifier comprises the optical antenna engaged to a rectifying material. Also, the solar cell comprises a metal layer wherein the metal layer surrounds the rectifier from the top of the substrate to the optical antenna, wherein the optical antenna accepts energy and converts the energy from AC to DC along the rectifier.

Further, the present invention discloses a solar cell comprising a planar substrate having a conductor layer below a semiconductor layer. In addition, the cell comprises an array of carbon nanotubes engaging the semiconductor layer at a first end and comprising an optical antenna at a second end. In addition, the solar cell comprises a passivation layer wherein the passivation layer surrounds a length of the carbon nanotubes, wherein the optical antenna accepts energy and delivers energy to the solar cell wherein AC is rectified to DC.

In addition, the present invention discloses methods of producing such solar cells. In an embodiment, a method is disclosed for producing a solar cell which comprises growing a plurality of vertically-aligned nanotubes on a substrate and depositing a layer of a rectifying material onto the nanotubes. In addition, the method comprises depositing a layer of metal to cover a length of the nanotubes.

### BRIEF DESCRIPTION OF THE DRAWINGS

The presently disclosed embodiments will be further explained with reference to the attached drawings, wherein like structures are referred to by like numerals throughout the several views. The drawings are not necessarily to scale, the emphasis having instead been generally placed upon illustrating the principles of the presently disclosed embodiments.

FIG. 1 is a schematic diagram showing an energy conversion device of the disclosed embodiments having a dipole antenna design.

FIG. 2 is a schematic diagram showing an energy conversion device of the disclosed embodiments having a bow-tie antenna design.

FIG. 3 is a schematic diagram showing an energy conversion device of the disclosed embodiments having a loop antenna design.

FIG. 4 is a schematic diagram showing an energy conversion device of the disclosed embodiments having a spiral antenna design.

FIG. 5 is a scanning electron microscopy image of an energy conversion device of the disclosed embodiments having a bow-tie antenna design.

FIG. 6 shows method steps for synthesizing an energy conversion device of the disclosed embodiments having a dipole antenna design.

FIG. 7 shows method steps for synthesizing an energy conversion device of the disclosed embodiments having a dipole antenna design.

FIG. 8 shows an example of a solar cell created using a number of energy conversion devices of FIG. 7.

FIG. 9 shows the electrical connections to the energy conversion device of FIG. 7.

FIG. 10 shows an energy conversion device of the disclosed embodiments having a CNT-semiconductor tunnel junction at a distal end of the CNT.

FIG. 11 shows an example of a solar cell configuration using a number of energy conversion devices.

FIG. 12 shows how large-scale assemblies of energy conversion devices can be formed where neighbor cells share a common cable to simplify connections.

FIG. 13A shows a scanning electron microscope (SEM) image of an array of aligned MWCNTs. FIG. 13B shows an SEM image of an array of scratched MWCNTs.

FIG. 14 shows a graph illustrating polarization effect.

FIG. 15 shows interference colors from the random array of MWCNTs.

FIG. 16 shows a graph illustrating reflected light intensity radiation wavelength measured in selected points on the sample shown in FIG. 15.

FIG. 17 shows calculated reflected light intensity spectra for a model array of random antennas for various nanotube lengths.

FIG. 18 shows average length of MWCNTs versus wavelength of the incoming radiation at the corresponding maxima of reflected light intensity.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

The embodiments disclosed herein relate to the field of energy conversion devices and more particularly to a solar cell using random arrays of nanotube optical rectennas. The following definitions are used to describe the various aspects and characteristics of the presently disclosed embodiments.

As referred to herein, “carbon nanotube”, “nanowire”, and “nanorod” are used interchangeably.

As referred to herein, “nanoscale” refers to distances and features below 1000 nanometers (one nanometer equals one billionth of a meter).

As referred to herein, “single-walled carbon nanotubes” (SWCNTs) consist of one graphene sheet rolled into a cylinder. “Double-walled carbon nanotubes” (DWCNTs) consist of two graphene sheets in parallel, and those with multiple sheets (typically about 3 to about 30) are “multi-walled carbon nanotubes” (MWCNTs).

As referred to herein, CNTs are “aligned” wherein the longitudinal axis of individual tubules are oriented in a direction substantially parallel to one another.

As referred to herein, a “tubule” is an individual CNT.

The term “linear CNTs” as used herein, refers to CNTs that do not contain branches originating from the surface of individual CNT tubules along their linear axes.

The term “array” as used herein, refers to a plurality of CNT tubules that are attached to a substrate material proximally to one another.

As referred to herein, a “catalytic transition metal” can be any transition metal, transition metal alloy or mixture thereof. Examples of a catalytic transition metal include, but are not limited to, nickel (Ni), silver (Ag), gold (Au), platinum (Pt), palladium (Pd), iron (Fe), ruthenium (Ru), osmium (Os), cobalt (Co), rhodium (Rh) and iridium (Ir). In an embodiment, the catalytic transition metal comprises nickel (Ni).

The terms “nanocrystals,” “nanoparticles” and “nanostructures,” which are employed interchangeably herein, are known in the art. To the extent that any further explanation may be needed, they primarily refer to material structures having sizes, e.g., characterized by their largest dimension, in a range of a few nanometers (nm) to about a few microns. In applications where highly symmetric structures are generated, the sizes (largest dimensions) can be as large as tens of microns.

The term “CVD” refers to chemical vapor deposition. In CVD, gaseous mixtures of chemicals are dissociated at high temperature (for example, CO₂ into C and O₂). This is the “CV” part of CVD. Some of the liberated molecules may then be deposited on a nearby substrate (the “D” in CVD), with the rest pumped away. Examples of CVD methods include but not limited to, “plasma enhanced chemical vapor deposition” (PECVD), “hot filament chemical vapor deposition” (HFCVD), and “synchrotron radiation chemical vapor deposition” (SRCVD).

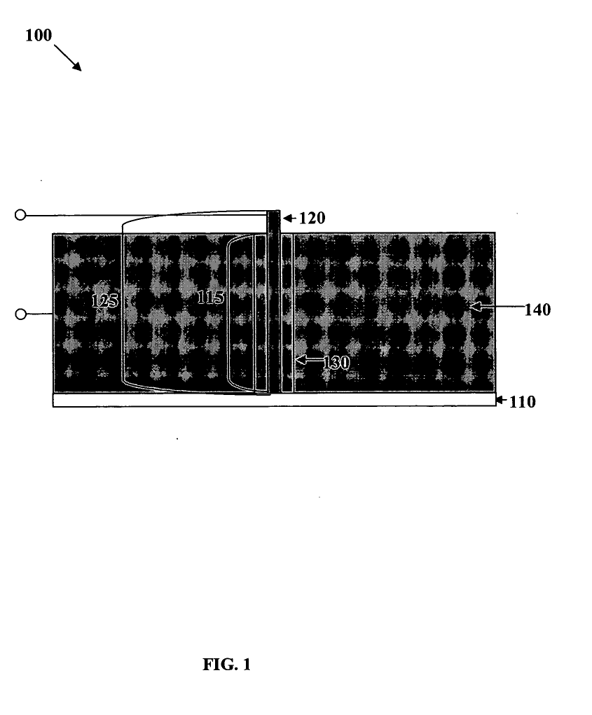

A nanoscale energy conversion device of the presently disclosed embodiments is shown generally at 100 in FIG. 1. As a brief overview, FIG. 1 shows an embodiment of an optical rectenna 125. The optical rectenna 125 engages a substrate 110 at a first end and comprises an optical antenna 120 at a second end. The optical antenna 120 receives energy from an outside source and delivers the energy to the solar cell 100. Further, FIG. 1 shows a rectifier 115 wherein the rectifier 115 comprises a rectifying material 130 engaged to the antenna. Various embodiments of each of these elements is discussed below.

Referring to FIG. 1, a nanoscale energy conversion device (solar cell) 100 includes a metal substrate 110 having an array of optical rectennas 125 penetrating the metal substrate 110 and extending beyond the top surface of the metal substrate 110. Only a single optical rectenna 125 is visible in FIG. 1, however, an array of optical rectennas 125 exists. The optical rectenna comprises an antenna engaged to a rectifying material 130. In an embodiment, the rectifying material 130 is an insulator. In an embodiment, the rectifying material is a semiconductor material 130. In an embodiment, the rectifying material 130 is air. In an embodiment, the rectifying material 130 is a vacuum. The rectifying material 130 may be engaged to the antenna, either before the antennas are grown on the metal substrate 110 or after they are grown on the metal substrate 110. A thick layer of metal 140 is deposited onto the optical rectennas 125 and portions of the optical rectennas 125 are exposed. The portions of the optical rectennas 125 that are exposed form optical antennas 120 and the portions of the optical rectennas 125 that are embedded in the thick layer of metal form the rectifier (in the form of transmission lines) 115. In an embodiment, the portion of the optical rectennas 125 that are exposed to the semiconductor material 130 (tunnel junction) results in a rectifying diode. In an embodiment, the semiconductor material 130 is coated onto the optical rectennas 125 after they are grown, such that the optical antenna-semiconductor junction produces a rectifying diode.

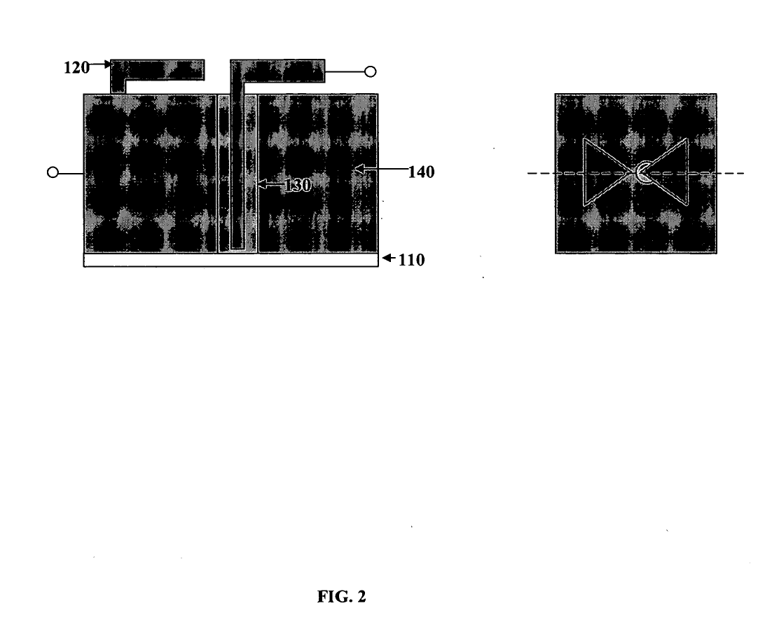

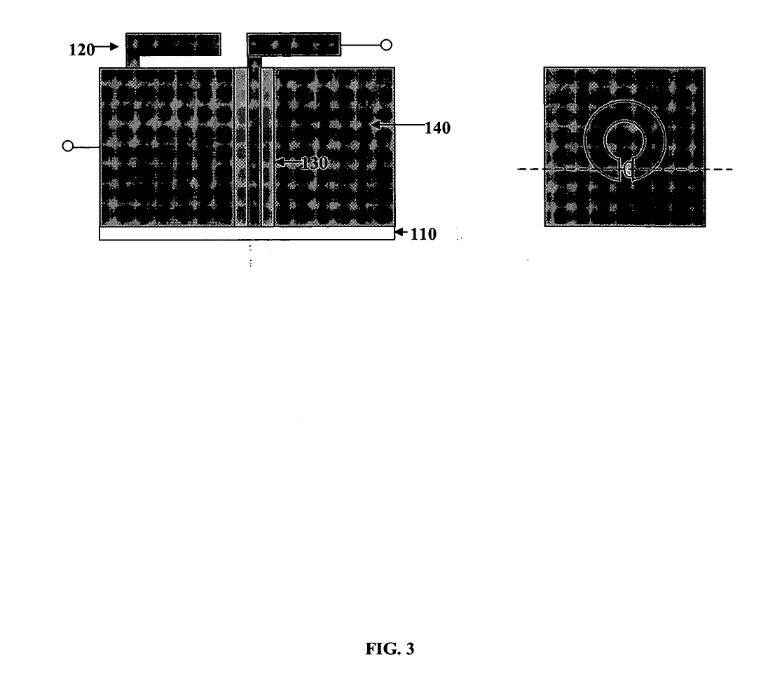

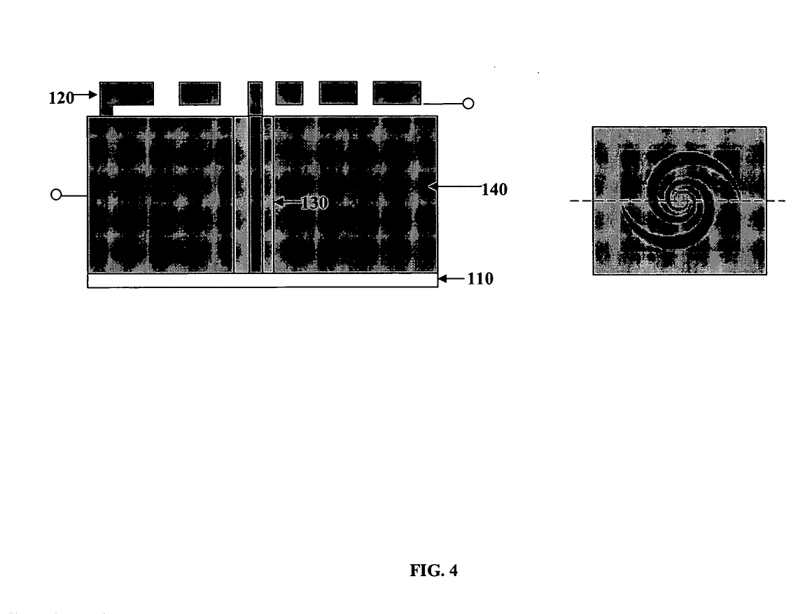

The rectifier 115 is capable of rectifying optical frequency alternating current (AC) into direct current (DC) electricity. The optical antennas 120 are connected to a nanowire electrode embedded in the metal substrate 110, in a vertical configuration (the rectifier section). The array of optical antennas 120 may form various geometric morphologies. In one embodiment, the geometric morphology of the optical antenna is similar to that of conventional microwave antennas. In one embodiment, the geometric morphology is a dipole antenna design. In one embodiment, the geometric morphology is a bow-tie antenna design (non-linear antenna design). In one embodiment, the geometric morphology is a loop antenna design (such as, an antenna forming a loop, parallel to the ground yielding a non-linear antenna design). In one embodiment, the geometric morphology is a spiral antenna design (non-linear antenna design). These designs are, shown respectively in FIGS. 1, 2, 3 and 4. These various configurations allow for the antennas to have various band-width response, various directional response patterns with respect to the direction of wave propagation as well as the polarization, and various impedance matching options. Those skilled in the art will recognize that various geometric configurations are within the spirit and scope of the present invention.

In one embodiment, the optical rectennas 125 may be fabricated from a metal nanorod. In one embodiment, the nanorod comprises aluminum. In one embodiment, the nanorod comprises gold. In one embodiment, the optical rectennas comprise carbon nanotubes. In one embodiment, the optical rectennas comprise a dielectric material. Those skilled in the art will recognize that the optical rectennas may comprise various materials and remain within the spirit and scope of the present invention.

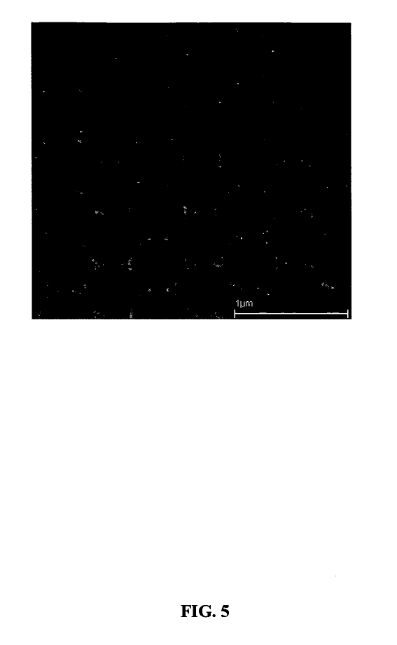

Techniques for fabricating the energy conversion device 100 include, but are not limited to, top-down electron beam lithography and bottom-up nanostructure synthesis. In an embodiment, the array of optical antennas 120 forms a dipole antenna design and fabrication of the optical rectennas 125 may be performed using aligned carbon nanotubes grown by a plasma-enhanced chemical vapor deposition method. In an embodiment, the array of optical antennas 120 forms a bow-tie antenna design and fabrication of the optical rectennas 125 may be performed using microsphere lithography where triangular islands with one edge facing each other can be achieved in large scale (as shown in the scanning electron microscopy image of FIG. 5).

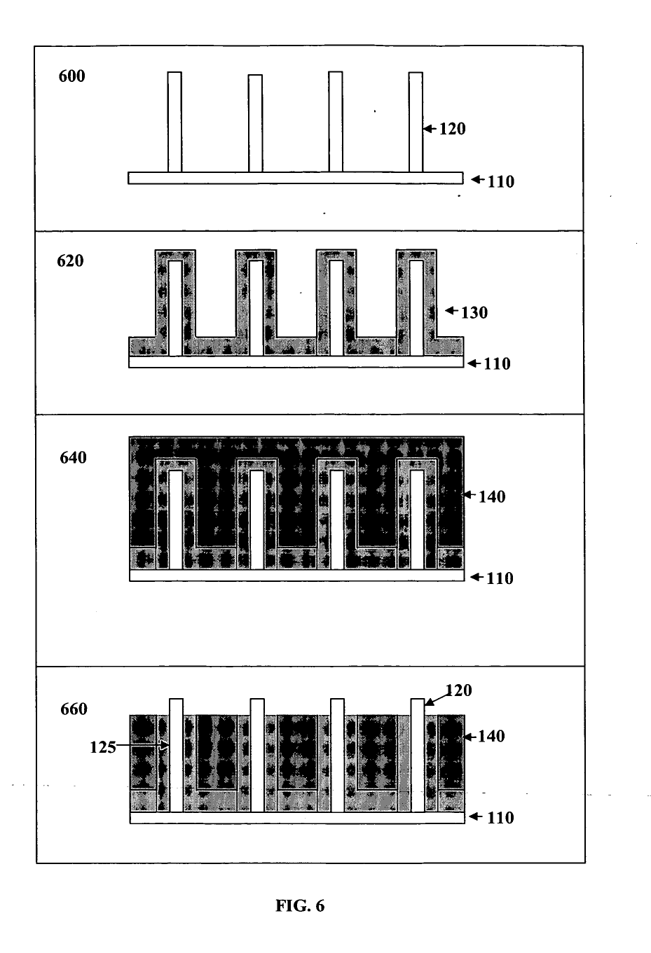

FIG. 6 illustrates a method of fabricating an energy conversion device 100 having a dipole nanoscale optical antenna design. In step 600, vertically-aligned optical rectennas 125 may be grown, or lithographically created on a metal substrate 110, that can be etched or dissolved later. In step 620, a thin intermediate layer, of an insulator 130 (including, but not limited to, SiO₂) or a semiconductor 130 (including, but not limited to, doped or undoped Si, SiC or GaAs), is deposited onto the recntennas 125. In step 640, a thick layer of metal 140 (including, but not limited to, Au or Ag) is deposited (by evaporation or sputtering) to cover the rectennas 125. In step 660, the surface of the device may be polished, causing the protruding optical antenna 120 tips to be broken up and removed together with the conductive materials coated on the tips, thus exposing the optical antennas 120 cross sections, as shown in step 660. The optical antennas 120 are in contact with the semiconductor material 130 resulting in a tunnel junction.

The material of the antenna 120 and rectifier 115 sections can be properly chosen to activate plasma resonances, resulting in an enhancement of the antenna 120 response. Nanostructures of gold and silver have plasmonic frequencies in the visible frequency range that may be tuned by changing the antenna 120 geometry. Thus, the electrical field response may be intensified by a factor of several orders of magnitude, both in the case of the antenna 120, as well as in the rectifier 115.

The configuration of the embedded rectennas 125 resembles that of a transmission line, impedance matching of which (to the antenna section) may be easily achieved. The energy collected by the antennas 120 will be concentrated in the transmission lines 115 (embedded in the metal substrate 140) where it is rectified and converted into electricity. The total area of the rectification area, e.g. the transmission line, may be of any size, not limited by the scale of the incident wavelength. The difference of the instantaneous electric field strength on the opposing antennas 120 and metal surfaces 140 causes electrons to tunnel through the intermediate layer (insulating or semiconducting) 130 having an asymmetric barrier height at the two junctions, resulting in net current flow.

When relatively narrow bandwidth antennas 120 are used, stacks of layers of rectenna structures 125 with different working frequencies may be used to respond collectively to a wide solar spectrum (for example, in a dipole design). Alternatively, the same could be achieved by implementing arrays of antennas 120 with random length. If in addition to random length a random orientation of antennas 120 is used, response to an unpolarized light will be maximized.

In an embodiment, a bottom-up procedure is used to fabricate high-efficiency energy conversion devices using random arrays of aligned multi-walled carbon nanotubes (MWCNTs) as the optical rectennas. The MWCNTs are synthesized on substrates by the plasma-enhanced chemical vapor deposition (PECVD) process. The bottom-up fabrication procedure utilizes MWCNTs both as the optical antennas and in the rectifying diodes. A configuration of MWCNT-semiconductor (CNT-Sc) tunnel junction is able to rectify optical frequency AC currents into DC currents. The CNT-Sc configuration features high reproducibility, low series resistance, and low cost.

The bottom-up fabrication procedure takes advantage of nanomaterial synthesis and novel transparent conductive materials and is carried out by a scalable layer-by-layer technique. The use of conductive and semiconducting transparent materials of the presently disclosed embodiments is compatible with large-scale industrial production. The high-efficiency energy conversion devices disclosed herein are capable of intrinsic energy conversion efficiencies of over about 80%, featuring amplified output current and minimum internal resistance. The characteristics of MWCNTs make the disclosed energy conversion devices useful in a variety of areas such as optoelectronic devices, such as THz and IR detectors and solar cells.

Aligned MWCNT arrays grown on silicon substrates using PECVD act as optical rectennas, receiving and transmitting light at ultraviolet (UV), visible and infrared (IR) frequencies. Most of the MWCNTs grown by PECVD methods are shown to be truly metallic. In addition, MWCNT-metal junctions have been found to be ohmic and MWCNT-semiconductor junctions have been found to have rectifying behaviors like schottky diodes. The work function of MWCNTs have been measured and found to be close to the work function of graphite which is highly conductive. Recent in situ tunneling electron microscopy studies have shown that the growth of MWCNTs starts off with several graphite layers parallel to the substrate surface at the CNT-substrate interface.

As is shown in example 1 below, it has been shown that MWCNTs interact with light in the same manner as simple dipole radio antennas. In particular, MWCNTs show both the polarization and the length antenna effect. The first effect is characterized by a suppression of the reflected signal when the electric field of the incoming radiation is polarized perpendicular to the CNT axis. The second, the antenna length effect, maximizes the response when the antenna length is a proper multiple of the half-wavelength of the radiation. The characteristics make the devices disclosed herein useful in a variety of areas such as optoelectronic devices, such as THz or and IR detectors.

To functionalize MWCNTs as optical rectennas, a femto-second rectifier must be engaged to each MWCNT to change the optical frequency AC current into DC current. An asymmetric metal-insulator-metal (MIM) tunnel junction structure has been disclosed for fabrication of such ultra-fast diodes. However, the methodology requires an unlimited selection range of materials and a very accurate control of the insulating layers thickness at the atomic scale. This greatly restricts the reproducibility and scalability in the practical process. For the case of MWCNTs as an example, the work function is restricted to about 4.9 eV which is prohibitively big compared to the visible frequency photon energy 1.8-3.2 eV The number of available transparent conductive materials is also very limited. Indium Tin Oxide (ITO) is one of such materials that is the most widely used in industry and has a work function in the range of 4.3eV-5.5 eV. Thus, the CNT-insulator-ITO junction will only work in the low-voltage scenario in both forward and reverse biases where the net current density is extremely small (<10⁻⁶ Acm⁻² for barrier thickness of 2 nm).

The disclosed embodiments provide for a CNT-Sc tunnel junction structure at one end of each individual CNT in order to form a rectifying diode. The CNT-Sc tunnel junction can be at either a distal end of the optical antenna (i.e., near the tip) or at a proximal end of the optical rectenna (i.e., at the end where the rectenna and the substrate are formed). The characteristics of the CNT-Sc tunnel junction resemble a conventional metal-semiconductor tunnel junction due to the intrinsic metallic property of the MWCNTs. The CNTs should have an average diameter of less than about 70 nm for significant quantum mechanical tunneling effect to dominate the thermionic emission. The choices of semiconductors are broad, and include, but are not limited to, heavily doped Si, GaAs, SiGe, Sic, and GaN (-type or n-type, doping density >10¹⁹ cm⁻³ for barrier thickness ˜3 nm). For multi-layer fabrications, transparent semiconductors are employed, including, but not limited to, ZnO:Al (AZO, n-type), SrCu₂O₂ (SCO, p-type), and CuAlO₂ (CAO, p-type), whose doping levels may be well controlled. Ohmic contacts to heavily doped silicon may be achieved by evaporating (sputtering) a catalytic material such as Al, Au, or Ni, onto the silicon and sintering at about 400° C. Ohmic contact to n-ZnO may be achieved by depositing n⁺-ZnO. Ohmic contact to p-SCO may be achieved by depositing In₂O₃:SnO₂ (ITO) onto the semiconductors at low temperature respectively. Sputtering targets of these oxide materials are widely available and suitable for large-scale production. The net forward tunneling current density of CNT-(p)Si heterojunctions has been shown to be on the order of 10⁻³ Acm⁻²-10⁻²Acm⁻² under a bias voltage of 1.8V-3.2V. The CNT-Sc tunnel junctions disclosed herein may result in a higher order of magnitude.

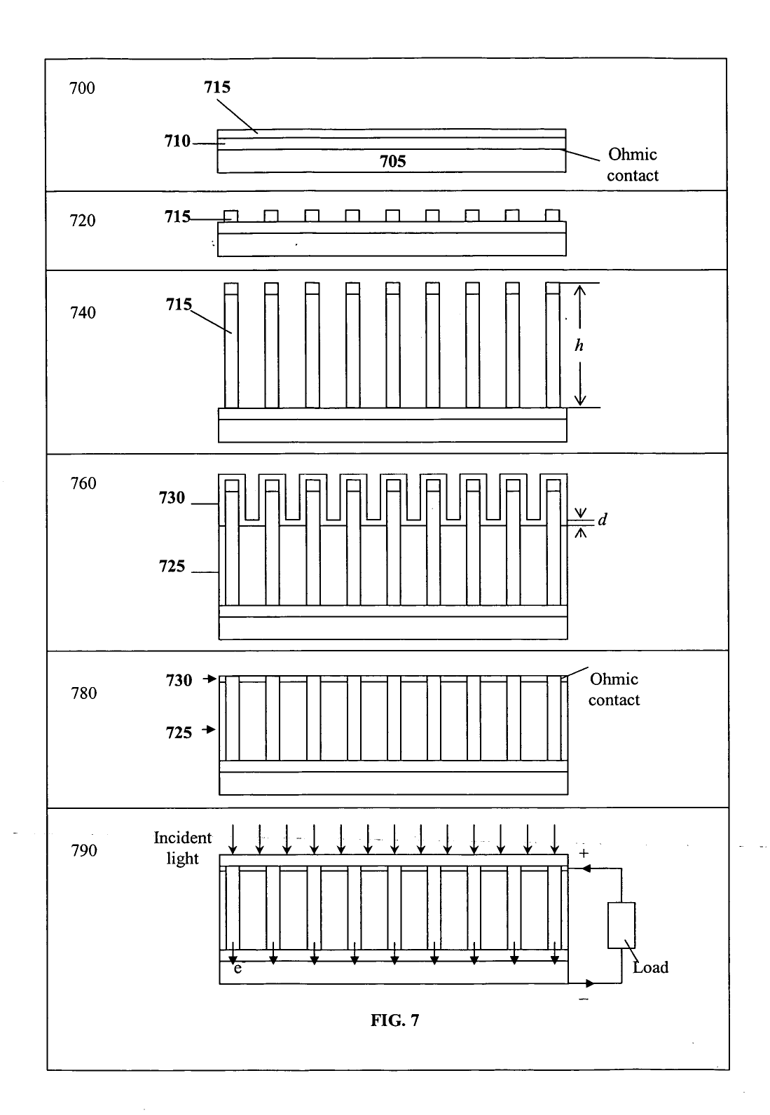

A method of fabricating an energy conversion device 700 using a bottom-up procedure is shown in FIG. 7. In step 700, a semiconducting thin film 710 (such as, p⁺-Si) is deposited onto a conductive substrate 705 (such as, Al), and standard procedures are carried out to form an ohmic contact. A catalytic material 715, such as, Ni, Fe, or Co, is deposited onto the semiconducting film 710 using DC magnetron sputtering. In an embodiment, the catalytic material 715 is Ni. The desired length and diameter of the carbon nanotubes (CNTs) are achieved by accurate control of the growth parameters. The deposition thickness of the catalytic material 715 has a direct affect on the average diameter of the aligned CNTs grown. Without being limited to any particular theory, the difference in the average diameter is most likely due to the fact that Ni films of different thicknesses break into catalytic particles of different average sizes by heat treatment during the growth procedure, step 720. Table 1 lists data showing the average diameters of aligned CNTs grown in a PECVD system resulting from different deposition thickness of Ni as the catalytic material 715. Clean aligned CNT 715 arrays with Ni particles on top can then be grown using a DC glow discharge plasma in an atmosphere of NH₃ and C₂H₂, as shown in step 740. Mixing ratios of about 4:1 or about 2:1 can be used. A growth time of about 1-2 min, yields CNTs 715 around or shorter than 1000 nm. The morphology of the CNTs 715 including length, diameters, straightness, etc., can be finely tuned by the other growth parameters such as plasma intensity and etching time, temperature, and total growth time. By modifying the growth parameters, and/or the geometry of the bias voltage electrodes, a nonuniform growth of CNTs 715, with average length varying across the sample, can also be achieved. In this configuration, at the bottom of each individual CNT 715, a nano-scale CNT-Sc tunnel junction is formed which rectifies the AC current excited within each antenna into a DC current at optical frequencies.

TABLE 1

| Ni film thickness (nm) | Average CNT diameter (nm) |
|---|---|
| 4 | 30 |
| 10 | 60 |
| 16 | 75 |
| 22 | 100 |
| 28 | 130 |

A highly transparent passivation layer 725 is then spin-coated in between the CNTs, as shown in step 760, up to a height h of λ/4n−d or λ/2n−d (50 nm-500 nm for visible and near infrared), where λ is the wavelength of incident light in vacuum and n is the refractive index of the passivation material 725. In an embodiment, the passivation layer 725 is a PMMA/copolymer layer, a silicone elastomer layer or another polymeric material layer. The spin-coating can be performed by varying the viscosity of the polymer solution and the spin rate. After baking (usually <200° C.), a thin film (thickness d<<λ/4n or λ/2n) of transparent conductive material 730 (such as Indium Tin Oxide (ITO) or n⁺-(Zinc Oxide (ZnO)) is deposited on top of the passivation layer 725 and the exposed part of CNTs 715 by e-beam evaporation or sputtering, as shown in step 760. The CNTs 715 grow sufficiently long (>λ/4n or λ/2n, respectively) so that, by carefully polishing the surface at this stage, the protruding CNT 715 tips will be broken up and removed together with the conductive materials coated on the tips, exposing the CNT 715 cross sections, as shown in step 780. The cross sections tend to be automatically closed or partially closed through the collapse of the CNT 715 walls near the open end. The CNT-transparent conductive material contacts are ohmic. An additional thin layer of the same passivation material 725 may be again spin-coated on top to provide a uniform dielectric medium surrounding the CNT antennas and protect the CNT antennas from outside attacks. A configuration where all the CNT rectennas 715 as individual current sources are connected in parallel is so achieved and the rectified DC currents will add up to a much higher magnitude accompanied by a substantially reduced total internal resistance of the rectennas 715. The two conductive layers can be connected across an external load as DC electrodes, as shown in step 790. The so-established single-wavelength energy conversion device, upon the incident light of wavelength λ polarized in the direction of CNT 715 alignment, will convert the photon energy into DC electricity at an efficiency greater then about 90%.

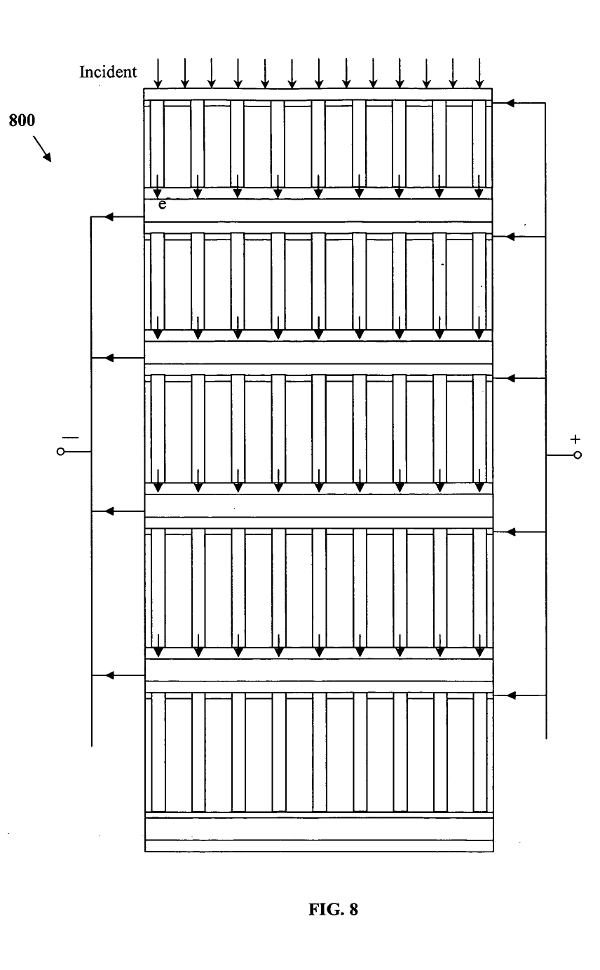

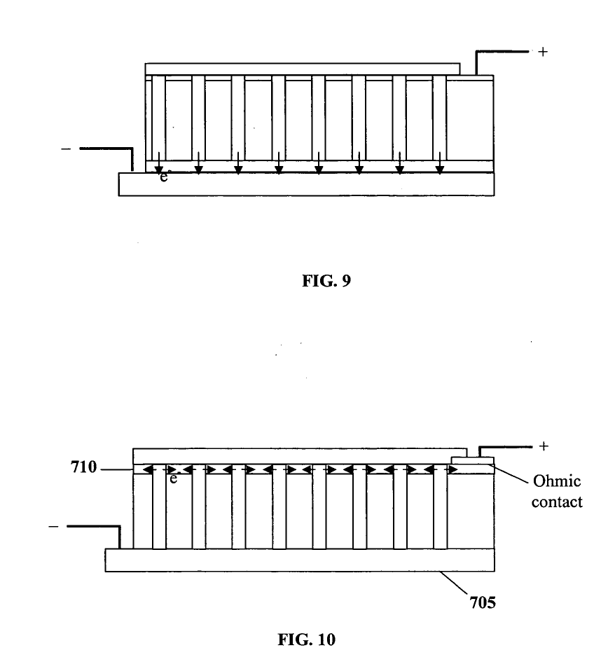

As shown in FIG. 8, a solar cell 800 that catches the whole solar spectrum is constructed by the following arrangement of single-wavelength energy conversion devices 700 disclosed in FIG. 7. The semiconducting films 710 and the substrates 705 are made of transparent materials. Devices 700 of different wavelength capabilities are cascaded together one below another. The ordering is such that the shorter the wavelength the upper the device 700 (in z direction), since it is easier for longer wavelength to penetrate through the media. All the devices 700 are then wired up in parallel to yield large current and small internal resistance. The electrical connections to each device 700 can be prepared during the original layer-by-layer construction process of the device 700 (see FIG. 9). The solar cell 800 disclosed herein is capable of collecting full solar spectrum of photons polarized in the CNT direction at an efficiency greater than about 85%.

As shown in FIG. 10, the order of the conductive film and the semiconducting film 710 can be interchanged by growing optical rectennas 715 from a conductive substrate 705 and depositing a semiconducting film 710 on the rectennas 715 later. Since the tip, side and bottom of CNTs have different atomic structures, there may be practical merits in this flexibility of changing the junction location. Another advantage of the top CNT-Sc junction configuration is that even smaller contact area can be achieved, if the thickness of the semiconducting film 710 is smaller than a quarter of the CNT diameter. It also means that the CNT diameter can be relatively large, which is easier for growth control and maintenance of CNT straightness during process, while still having a small enough contact area to reduce the parasitic capacitance and increase the switching frequency of the CNT-Sc junction by making the semiconducting film 710 sufficiently thin.

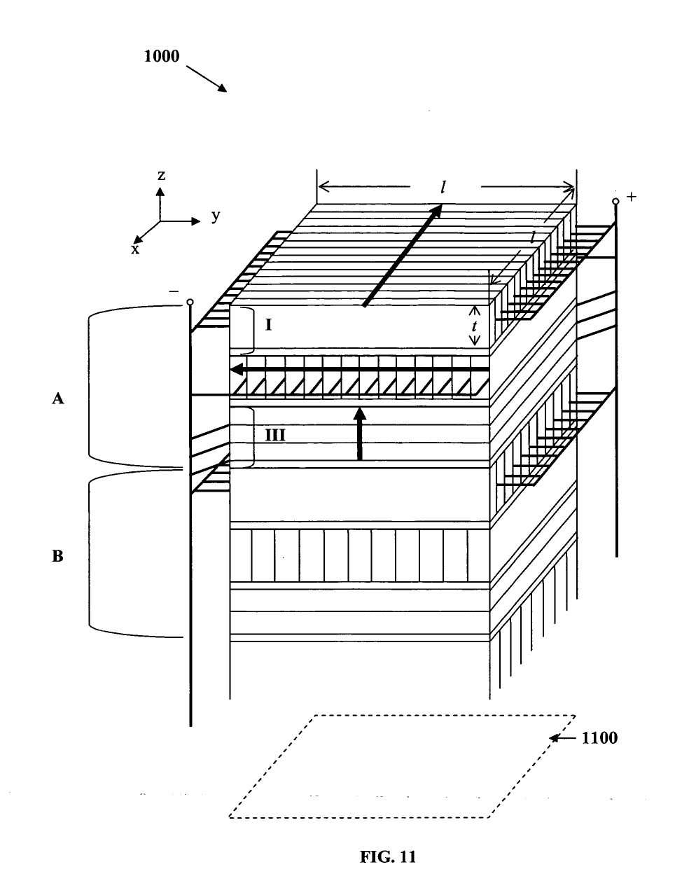

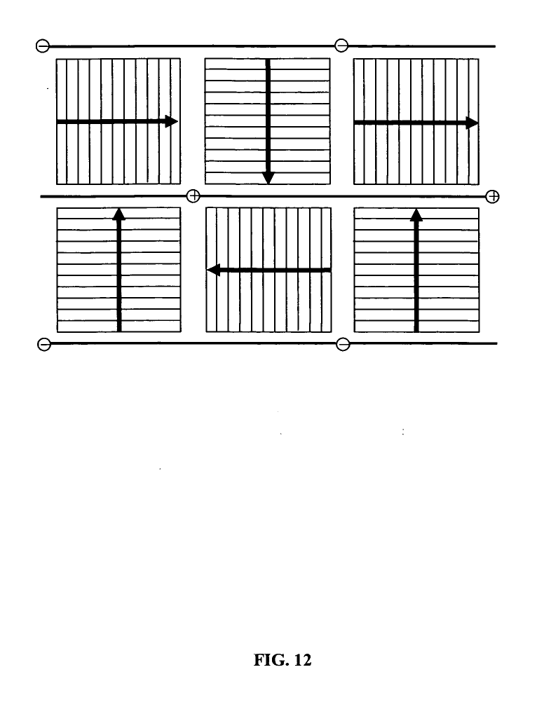

FIG. 11 shows an embodiment of a solar cell 1000, where full spectrum unpolarized sunlight may be efficiently converted to DC electricity. The solar cell 1000 is composed of multi-levels (for simplicity, two levels A and B are shown) with shorter wavelength energy conversion devices 1050 closer to the exposed surface and longer ones farther away. Within a single level, there are three sublevels (I, II and III), each consisting of a stack of identical single-wavelength energy conversion devices 1050. The solid arrows denote the CNT growth directions in the stacks. The three stacks (I, II and III) are so oriented that the CNT array in each aligns with a different orthogonal 3-dimensional axis. The two sublevels of CNTs parallel with the exposed surface (in x-y plane) may be made as wide as possible (l>>10 μm) but have to be sufficiently thin (t<10 μm, ˜100 CNT layers) by using devices of strip-shaped substrates for good transmission. Fabrication of substrate strips at this scale may be achieved using contemporary photolithography. The other sublevel in which CNTs are oriented perpendicular to the exposed surface (in z direction) has no limitations in dimensions but the number of devices in a stack, which are larger dimension devices, is compensated so that every sublevel contains similar number of CNTs. The three sublevel configurations (I, II and III) are repeated from one level to another. Although in levels of longer CNTs, an increment in the thickness of the two parallel sublevels seems necessary for maintaining an equivalent CNT quantity to that in shorter CNT levels, the fact that the solar radiation has lower power in longer wavelengths actually predicts a lower demand for the quantity of longer CNTs, thus ensuring no significant change in level thickness along the z direction. If the average bandwidth of each level is about 50 nm (high selectivity) for half-wave antennas according to surface plasmon measurements, the total solar cell thickness should be on the order of about 1 mm. Currently, the best transparent polymeric material has a transmittance of over 95% at this scale of thickness. The solar cell device 1000 is supported on the bottom by a reflecting mirror 1100 facing up for secondary absorption.

According to the electrical connection pattern shown in FIG. 11, all the energy conversion devices 1050 are connected in parallel and the currents merge into two major cables located besides the diagonal ridges of the solar cell 1000, resulting in a useful setup when producing large dimension single solar cells is practically prohibitive. The setup allows multiple solar cells to be further integrated into large-scale assemblies where neighbor cells share a common cable to simplify connections (FIG. 12, top view). All the cables terminate on the surface, ready to be finally collected by a set of parallel wires. The energy conversion efficiency of the solar cell device 1000 is greater then about 80%.

The following provides an example of an embodiment of the current invention. The example in no way is meant to limit any aspect of the current invention.

### EXAMPLES

### Example 1

With this example, optical measurements of random arrays of aligned carbon nanotubes are disclosed, and show that the response is consistent with conventional radio antenna theory. The example first demonstrates the polarization effect, the suppression of the reflected signal when the electric field of the incoming radiation is polarized perpendicular to the nanotube axis. Next, the example demonstrates the interference colors of the reflected light from an array, and show that they result from the length matching antenna effect. This antenna effect could be used in a variety of optoelectronic devices, including THz and IR detectors.

In recent years, periodic and random arrays of multi-walled carbon nanotubes (MWCNTs) have been synthesized on various substrates, by the plasma-enhanced chemical vapor deposition (PECVD) process. Each nanotube in such arrays is a metallic rod of about 50 nm in diameter and about 200 to about 1000 nm in length. Therefore, one can view interaction of these arrays with the electromagnetic radiation as that of an array of dipole antennas. Since the most efficient antenna interaction occurs when the length of the antennas is of the order of the wavelength of the incoming radiation, the example expects an antenna-like interaction of MWCNT arrays with visible light. There are two major antenna effects. First, the polarization effect suppresses the response of an antenna when the electric field of the incoming radiation is polarized perpendicular to the dipole antenna axis. Second, the antenna length effect maximizes the antenna response when the antenna length is a multiple of half-wavelength of the radiation. The polarization antenna effort has already been observed in the Raman response of single-walled carbon nanotubes. The nanoscopic dipole antenna length effect was recently observed in microbolometer, stripline antenna. This example demonstrates both of these antenna effects in random MWCNT arrays. This example utilizes random nanotube arrays to suppress the intertube diffraction, which obscures the intratube antenna effects that are of interest here.

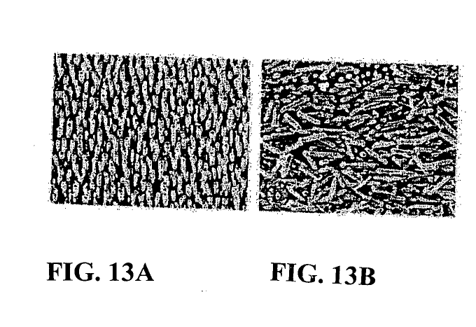

The MWCNT arrays of this example are fabricated using PECVD. The silicon substrate is coated with a thin film of nickel catalyst (about 20 nm) in a dc magnetron sputtering system, that is then heated to about 550-600 ° C. in a PECVD reaction chamber to break up the nickel film into small catalyst particles. A gas mixture NH₃ and C₂H₂ is introduced into the PECVD chamber at the ratio of 2:1, and a dc glow discharge plasma is then generated and maintained by a bias voltage of about 500-550V. A growth time of about 1-2 minutes yields nanotubes around or shorter than 1000 nm. FIG. 13A shows the scanning electron microscope (SEM) image of such an array or random MWCNTs. By modifying the growth parameters, and/or the geometry of the bias voltage electrodes, a nonuniform growth of nanotubes, with average length varying across the sample, can also be achieved. This has been utilized to produce the samples used in the present example.

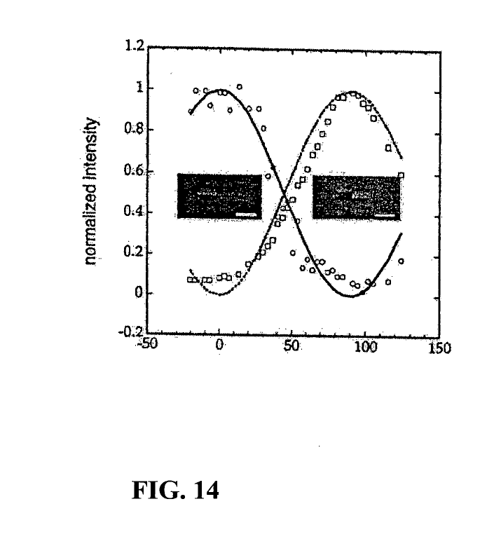

The example first demonstrates the polarization effect. A small piece of silicon wafer (2×1 cm²) was coated with a thin film of Cr. Subsequently, one-half of the sample was coated with a thin film of Ni catalyst, and processed to grow a random array of MWCNTs. The sample was illuminated with white unpolarized light, and observed in a specular direction through a rotation polarizer. FIG. 14 shows that when the polarizer is oriented parallel to the growth direction of the nanotubes (orientation angle θ=0°), the light reflected from the array is clearly visible, while the exposed metallic half of the sample is dark (not reflecting). With increasing (or decreasing) angle θ, intensity of the light reflected from the nanotube array diminishes, while the intensity reflected from the metallic side increases until at θ=90°, the radiation is observable essentially only from the metallic side.

This behavior follows from the fact that, while in nanotubes currents are excited predominantly along their length, in the metallic film, currents flow in the film plane; that is perpendicular to the nanotubes. Each nanotube acts as an antenna reradiating light with the electric field E, polarized in the plane parallel to the antenna. A polarizer, with its axis of polarization rotated by an angle θ to this plane, transmits radiation with a projected electric field E′=Ecos θ, and therefore the corresponding observed intensity is given by the law of Malus I_{NT} is proportional to (E″)²=E²cos²θ (solid line circles in FIG. 14). For light reflected from the metallic film the situation is exactly “out-of-phase” with that of the array; that is, Imetal is proportional to (E″)²=E²sin²θ (dotted line-squares in FIG. 14).

The second characteristic of an antenna is its resonant response behavior as a function of the radiation wavelength. This results from the condition that the induced current oscillations must “fit” into the antenna length (i.e., satisfy the boundary conditions at the antenna ends). A general equation describing the scattering maxima from a random array of dipole antennas (with vanishing current at each end) is:
L=m(λ/2)f(θ,n), (1)
where f(θ,n)=1 for a single, simple diode, and f(θ,n)=(n²-sin²θ)^{-1/2} in the limit of the very dense array (thin film limit), where the average interantenna distance D<λ, f(θ,n) is equal to about 1., and is only weakly dependent on the angle θ. As such, similar behavior is expected for the random array of MWCNTs.

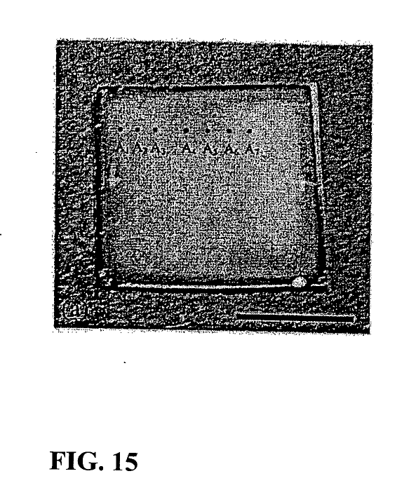

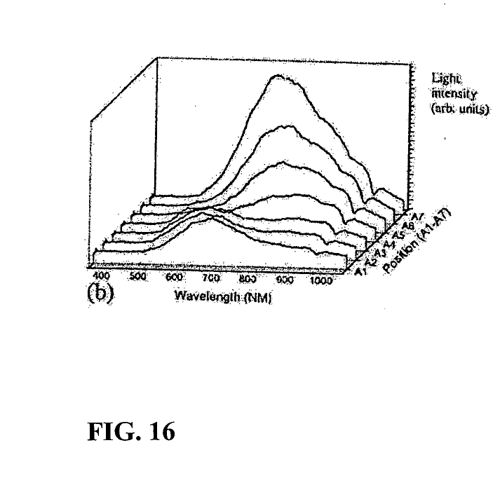

FIG. 15 shows a sample of random array of nanotubes with gradually reduced lengths (from left to right(illuminated by white light. The strong interference colors are due to the antenna length effect. FIG. 16 shows the intensity of the reflected light at the specular direction versus the radiation wavelength of the incoming radiation measured at selected spots (positions A1-A7) of the sample shown in FIG. 15. Experiments were done using the Ocean Optics USB2000 Fiber Optic Spectrometer (FOS). White light emerging from a 50-μm-diameter finer was focused onto the sample surface at about a 30 degree angle of incidence. Incident spot size was of the order of about 0.5 mm. A receiving fiber with a 1 mm diameter is positioned to collect light reflected spectrally from the sample surface. The system was first corrected for dark field and then normalized with respect to the tungsten light source and reflectance from the silicon substrate at the 30° incident angle. Another sample, with longer nanotubes, produced insufficient scattered light intensity for the FOS, and the wavelength was estimated using a high sensitivity CCD camera and optical filters, with accuracy of about 10%. The exact positions at which the data were acquired were permanently marked (scratched with a needle) on each of the samples. The SEM pictures were then used to estimate the average nanotube length at each marked spot. To minimize the parallax error of this estimate, only the collapsed (lying flat on the surface) nanotubes in the scratched area was measured.

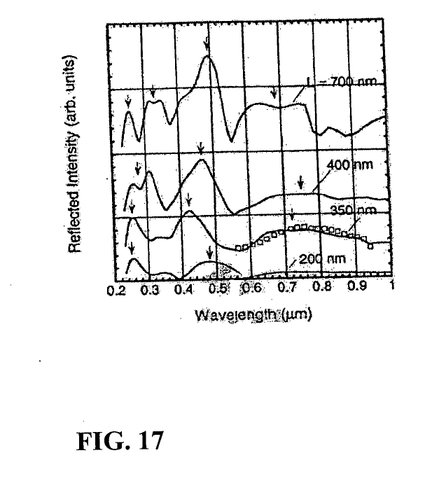

In addition to the experiments described herein, computer simulations of the electromagnetic response from a random dipole antenna array have been performed. The array was modeled as a set of 10 parallel, equal-length antennas, randomly distributed on, and perpendicular to, a flat substrate. Antenna dimensions and the average interantenna distance represent the actual nanotube array. The dielectric constant of the substrate is assumed to be real and equal to 10. The resulting reflection curves for various antenna lengths are shown in FIG. 17.

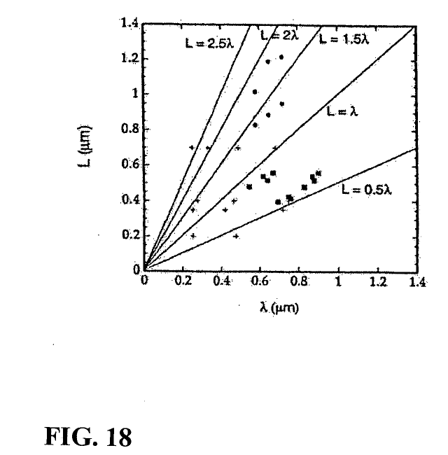

FIG. 18 combines the experimental and theoretical results to demonstrate the antenna length effect. In FIG. 18, positions of the various reflected intensity maxima are plotted versus the corresponding average antenna length L. Solid lines represent the ideal dipole antenna condition [Eq. (1), with f=1] for different m. The measured results are represented as solid circles and squares. Crosses mark positions of the distinct maxima of the theoretical curves. Arrows indicate those maximas in FIG. 17. It is clear that both experimental and theoretical results follow closely the ideal dipole antenna condition, and thus demonstrate that MWCNTs can act as light antennas.

This example also estimates the quality of the nanotube antennas. FIG. 17 shows a comparison between one of the experimental curves of FIG. 16 (for position A₅) shown as squares, and the corresponding calculated response. This comparison shows that the calculation, which assumed infinite conductivity of the metallic antenna, reproduces well the measured line width of the peak. Therefore, the peak width is primarily due to the radiation losses of currents induced inside the nanotubes. As such, this example concludes that the actual scattering rate of the conducting electrons (y) in the nanotube antenna must be much less that the width of the peak in FIG. 17. After replotting the peak versus frequency (rather than the wavelength), the example finds that the width is about 10^{15s-1}, and therefore y must be of the order 1014s⁻¹ or less. This is a very low scattering rate of the order of (or better than) that for good metals such as copper.

The fact that MWCNTs act as high quality light antenna suggests various applications based on the radio analogy. For example, a THz demodulator could be built, if a sufficiently fast diode is attached to (or built into) each antenna in the array mounted on a THz stripline. The modulating THz signal could then be seamlessly introduced into the stripline by shining modulated light onto the array. This scheme could be used in a new generation of THz and possibly IR detectors. The antenna length effect can be tuned by controlling the nanotube length, and to some extent the array density during the growth process, making the devices frequency selective. In principle, the antenna effects should be also detectable in, and the same applications possible with, arrays of aligned single-walled nanotubes. However, at this moment, no scheme for making such arrays of all metallic single-walled nanotubes exists, and there is no reason to believe that such a system would have any advantage over those based on MWCNTs.

In conclusion, this example demonstrates that MWCNTs interact with light in the same manner as simple diode radio antennas. In particular, they show both the polarization and the length antenna effect. The first effect is characterized by a suppression of the reflected signal when the electric field of the incoming radiation is polarized perpendicular to the nanotube axis. The second, the antenna effect, maximizes the response when the antenna length is a proper multiple of the half-wavelength of the radiation. These effects could be used in a variety of optoelectronic devices, such as THz and/or IR detectors.

All patents, patent applications, and published references cited herein are hereby incorporated by reference in their entirety. It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A solar cell comprising:
a planar substrate having a top side and a bottom side;
an at least one optical antenna comprising a geometric morphology capable of accepting energy;
a rectifier having the optical antenna at a first end and engaging the substrate at a second end wherein the rectifier comprises the optical antenna engaged to a rectifying material; and
a metal layer wherein the metal layer surrounds a length of the rectifier,
wherein the optical antenna accepts energy and converts the energy from AC to DC along the rectifier.

2. The cell of claim 1 wherein the geometric morphology of the optical antenna is a bow-tie morphology.

3. The cell of claim 1 wherein the geometric morphology of the optical antenna is a loop morphology.

4. The cell of claim 1 wherein the geometric morphology of the optical antenna is a spiral morphology.

5. The cell of claim 1 wherein the optical antenna comprises carbon nanotubes.

6. The cell of claim 1 wherein the optical antenna comprises an aluminum nanorod.

7. The cell of claim 1 wherein the optical antenna comprises a gold nanorod.

8. The cell of claim 1 wherein the rectifying material is a semiconductor.

9. The cell of claim 9 wherein the semiconductor is selected from the group consisting of doped silicon, undoped silicon, silicon carbide and GaAs.

10. The cell of claim 1 further comprising a plurality of optical antennas.

11. The cell of claim 10 wherein the plurality of optical antennas are of random lengths.

12. The cell of claim 10 wherein the plurality of optical antennas are of random orientation.

13. A solar cell comprising:
a planar substrate having a conductor layer below a semiconductor layer;
an array of carbon nanotubes engaging the semiconductor layer at a first end and comprising an optical antenna at a second end; and
a passivation layer wherein the passivation layer surrounds a length of the carbon nanotubes,
wherein the optical antenna accepts energy and delivers energy to the solar cell wherein AC is rectified to DC.

14. The cell of claim 13 wherein the passivation layer comprises a polymeric material.

15. The cell of claim 13 further comprising a transparent conductive layer above the passivation layer.

16. The cell of claim 15 further comprising a second passivation layer above the transparent conductive layer.

17. A method for producing a solar cell, comprising:
growing a plurality of vertically-aligned nanotubes on a substrate;
depositing a layer of a rectifying material onto the nanotubes; and
depositing a layer of metal to cover a length of the nanotubes.

18. The method of claim 17 wherein the nanotubes are carbon nanotubes.

19. The method of claim 17 wherein the rectifying material is a semiconductor.

20. The method of claim 17 wherein the rectifying material is selected from the group consisting of air, a vacuum, and an insulator.
